(19) United States
(12) Patent Application Publication
(10) Pub. No.: US 2026/0120749 A1
(43) Pub. Date: Apr. 30, 2026

(54) CONFIGURED COMMAND EXCLUSIONS FOR IMPROVED HIGH-BANDWIDTH MEMORY DEVICES

(71) Applicant: Micron Technology, Inc., Boise, ID (US)

(72) Inventors: Yasir Husain, Folsom, CA (US); Sujeet Ayyapureddi, Boise, ID (US)

(21) Appl. No.: 19/329,543

(22) Filed: Sep. 15, 2025

Related U.S. Application Data
(60) Provisional application No. 63/712,910, filed on Oct. 28, 2024.

(51) Int. Cl. G11C 11/4076; H01L 25/065; H01L 25/18; H10B 80/00

(52) U.S. Cl. CPC G11C 11/4076; H10B 80/00; H10W 90/00; H10W 90/297

(57) ABSTRACT

A SiP device includes a processing unit and a HBM device. The HBM device includes a plurality of TSV buses associated with a same channel and one or more SIDs. Each SID has one or more dies and each die includes a plurality of command decoder circuits associated with the same channel. A bus switching circuit selects a TSV bus from the plurality of TSV buses and communicatively couples a command signal bus to the selected TSV bus. Based on an exclusion timing parameter communicated from the HBM device, the processing unit can be configured such that, after transmitting a first command signal to a first SID of the one or more SIDs, a second command signal to the first SID is not transmitted at a clock edge that is N CLK cycles from the transmission of the first command signal, where N corresponds to a ratio of t_{CCDL}/t_{CCDS}.

### CROSS-REFERENCE TO RELATED APPLICATION(S)

The present application claims priority to U.S. Provisional Patent Application No. 63/712,910 , filed Oct. 28, 2024, the disclosure of which is incorporated herein by reference in its entirety.

### TECHNICAL FIELD

The present technology is generally related to vertically stacked semiconductor memory devices and more specifically to systems and methods for improving the bandwidth of high-bandwidth memory devices of a system-in-package.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller devices. To meet market demands, semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet market demands, such as by increasing operating speeds, can often introduce challenges in other aspects, such as maintaining circuit robustness and/or power consumption.

### BRIEF DESCRIPTION OF THE DRAWINGS

FIG. 1 is a partially schematic cross-sectional diagram of a related art system-in-package device.

FIG. 2A is a partial block diagram of a related art high-bandwidth memory (HBM) device showing a command TSV bus for a channel.

FIG. 2B is a simplified related art timing diagram for command signal flow through the command TSV bus of a channel of a related art HBM device.

FIG. 3A is a partially schematic cross-sectional diagram of a system-in-package device that is consistent with the present disclosure.

FIG. 3B is a block diagram of an embodiment of a HBM device that is consistent with the present disclosure.

FIG. 4A is a schematic block diagram of a bus switching circuit that can be incorporated in an HBM device that is consistent with the present disclosure.

FIG. 4B is an embodiment of a switch than be used in a bus switching circuit that is consistent with the present disclosure.

FIG. 5 is a simplified timing diagram for command signal flows to the same command decoder circuit in an HBM device without exclusion timing parameters.

FIG. 6 is a simplified timing diagram for command signal flows through a channel that is consistent with the present disclosure.

FIG. 7 is a flow chart that shows a method of communicatively coupling a command signal bus to a TSV bus that is consistent with the present disclosure.

The drawings have not necessarily been drawn to scale. Further, it will be understood that several of the drawings have been drawn schematically and/or partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

High data reliability, high speed of memory access, higher data bandwidth, lower power consumption, and reduced chip size are features that are demanded from semiconductor memory. In recent years, vertically stacked memory devices have been introduced, often referred to as 2.5-dimensional (“2.5D”) memory devices when placed adjacent to a host device or 3-dimensional (“3D”) memory devices when stacked on top of the host device. Some 2.5D and 3D memory devices are formed by stacking memory dies vertically and interconnecting the dies using through-silicon (or through-substrate) vias (TSVs). The memory dies can be grouped in “stacks” with each stack, designated by a stack ID (“SID”), having one or more dies (e.g., 4 dies). Benefits of the 2.5D and 3D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 2.5 and 3D memory devices contribute to higher memory access speed, lower power consumption, and chip size reduction. Example 2.5D and/or 3D memory devices include Hybrid Memory Cube (HMC) and High-Bandwidth Memory (HBM). For example, HBM is a type of memory that includes a vertical stack of dynamic random-access memory (DRAM) dies and an interface die (which, e.g., provides the interface between the DRAM dies of the HBM device and a host device). In the description below, the terms “stack” and “SID” are used interchangeably.

In a system-in-package (SiP) configuration, HBM devices may be integrated with a host device (e.g., a graphics processing unit (GPU), computer processing unit (CPU), a tensor processing unit (TCU), and/or any other suitable processing unit) using a base substrate (e.g., a silicon interposer, a substrate of organic material, a substrate of inorganic material and/or any other suitable material that provides interconnection between GPU/CPU and the HBM device and/or provides mechanical support for the components of a SiP device) through which the HBM devices and host communicate. Because traffic between the HBM devices and host device resides within the SiP (e.g., using signals routed through the silicon interposer), a higher bandwidth may be achieved between the HBM devices and host device than in conventional systems. In other words, the TSVs interconnecting DRAM dies within an HBM device, and the silicon interposer integrating HBM devices and a host device, enable the routing of a greater number of signals (e.g., wider data buses) than is typically found between packaged memory devices and a host device (e.g., through a printed circuit board (PCB)). The high bandwidth interface within a SiP enables large amounts of data to move quickly between the host device (e.g., GPU/CPU/TCU, etc.) and HBM devices during operation. For example, the high bandwidth channels can be on the order of 1000 gigabytes per second (GB/s, sometimes also referred to as gigabits (Gb)). As a result, the SiP device can quickly complete computing operations once data is loaded into the HBM devices. SiP devices, in turn, are typically integrated with a package substrate (e.g., a PCB) adjacent to other electronics and/or other SiP devices within a packaged system. It will be appreciated that such high bandwidth data transfer between the host device and the memory of HBM devices can be advantageous in various high-performance computing applications, such as video rendering, high-resolution graphics applications, artificial intelligence and/or machine learning (AI/ML) computing systems and other complex computational systems, and/or various other computing applications.

Market demands on SiP devices and/or the HBM devices therein can present certain challenges, however. For example, there is a demand for continued improvement of the performance of SiP devices and the HBM devices therein. One approach to improving performance has been to increase the speed of the interface between HBM devices and other devices of the SiP (such as a host device) by increasing the bandwidth of the interface and/or the frequency of the interface. For example, and as described herein, there has been a demand to increase the clock speed associated with host commands transmitted to HBM devices (so that more commands can be transmitted by the host within a fixed period of time), and therefore an increase in corresponding command signal rates. With increased command signal rates, there has been a corresponding need to increase the speed of command TSV bus circuits (used to propagate commands throughout the HBM device) and command decoder circuits (used to decode the propagated commands). To meet these demands, some HBM devices have consumed more power and/or utilized faster transistors. As described below, one way to mitigate the increased timing demands on command TSV bus circuits, while supporting increased bandwidths and/or increased command signaling rates between a host and HBM device, is to increase the number of command signal paths within the HBM device (e.g., by utilizing multiple command TSV busses per channel). However, if the number of command decoding circuits remain the same as in related art HBM devices, a contention can occur where a new command signal is sent to a command decoding circuit that is busy decoding a previously sent command signal. To avoid this contention, the number of command decoding circuits can be increased. However, because the core die area in memory devices may be limited, increasing the number of command decoder circuits may not be a desirable option. Accordingly, it is desirable to increase the bandwidth of the HBM device while maintaining the same timings with respect to, for example, the command TSV buses and the command decoder circuits (and eliminate or minimize the need for faster transistors), while keeping the same number of command decoding circuits as in related art HBM devices, and while keeping power consumption as low as possible.

As used herein, the terms “vertical,” “lateral,” “upper,” “lower,” “top,” and “bottom” can refer to relative directions or positions of features in the devices in view of the orientation shown in the drawings. For example, “bottom” can refer to a feature positioned closer to the bottom of a page than another feature. These terms, however, should be construed broadly to include devices having other orientations, such as inverted or inclined orientations where top/bottom, over/under, above/below, up/down, and left/right can be interchanged depending on the orientation.

Further, although primarily discussed herein in the context of 2.5D HBM devices for SiP devices, one of skill in the art will understand that the scope of the present disclosure is not so limited. For example, various components of the SiP devices described herein can also be implemented in 3D HBM devices and various other stacked semiconductor devices to help with issues related to high data rates as discussed above. Accordingly, the scope of the present disclosure is not confined to any subset of embodiments and is confined only by the limitations set out in the appended claims.

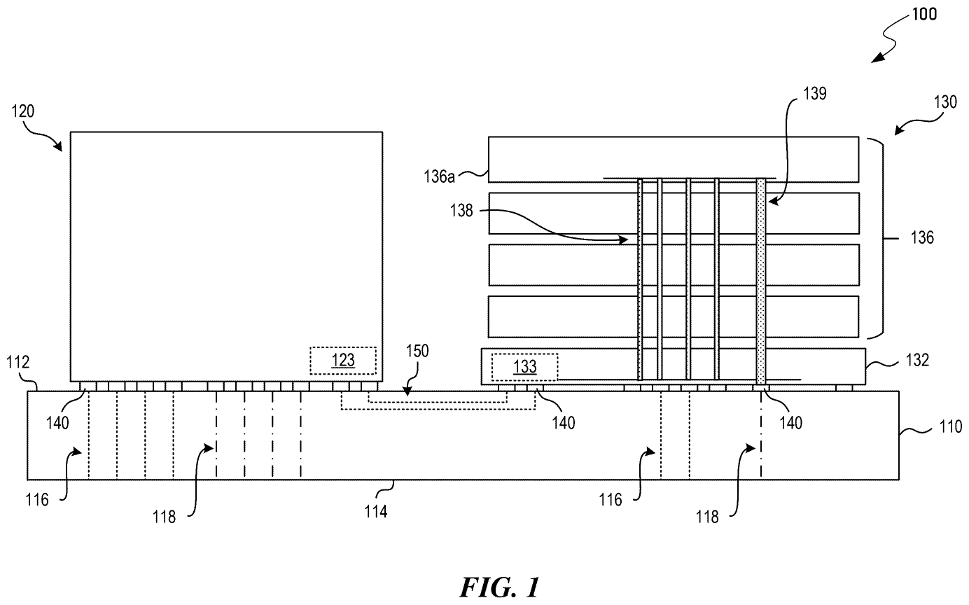

FIG. 1 is a partially schematic cross-sectional diagram of a related art SiP device 100. As illustrated in FIG. 1, the SiP device 100 includes a base substrate 110 (e.g., a silicon interposer, another organic interposer, an inorganic interposer, and/or any other suitable base substrate), as well as a host device 120 and an HBM device 130 each integrated with (e.g., carried by and coupled to) an upper surface 112 of the base substrate 110 through a plurality of interconnect structures 140 (three labeled in FIG. 1). The interconnect structures 140 can be solder structures (e.g., solder balls), metal-metal bonds, and/or any other suitable conductive structure that mechanically and electrically couples the base substrate 110 to each of the host device 120 and the HBM device 130. Further, the host device 120 is coupled to the HBM device 130 through one or more communication channels 150 formed in the base substrate 110. The communication channels 150 can include one or more route lines (two illustrated schematically in FIG. 1) formed into (or on) the base substrate 110.

As further illustrated in FIG. 1, the base substrate 110 includes a plurality of external signal TSVs 116 and a plurality of external power TSVs 118 extending between the upper surface 112 and a lower surface 114 of the base substrate 110. The external signal TSVs 116 can communicate signals (e.g., data, control signals, processing commands, and/or the like) between the host device 120 and/or the HBM device 130 and an external component (e.g., a PCB the base substrate 110 is integrated with, an external controller, and/or the like). The external power TSVs 118 provide electrical power to the host device 120 and/or the HBM device 130 from an external power source.

In the illustrated environment, the host device 120 can include a variety of components, such as a processing unit (e.g., CPU/GPU/TCU, etc.), one or more registers, one or more cache memories, and/or a variety of other components. For example, in the illustrated environment, the host device 120 includes a host IO circuit 123 that can direct signals to and/or from the HBM device 130 through the communication channels 150. Additionally, or alternatively, the host IO circuit 123 can direct signals to and/or from an external component (e.g., a controller coupled to one or more of the external signal TSVs 116 and/or the like).

The HBM device 130 can include an interface die 132 and a stack of one or more memory stacks 136 (four illustrated in FIG. 1) carried by the interface die 132. Each of the memory stacks 136 can include one or more DRAM dies (not shown in FIG. 1). Each memory stack 136 may encompass a physical and/or logical arrangement of one or more dies and can be associated with a stack ID (SID). The HBM device 130 also includes one or more signal TSVs 138 (four illustrated in FIG. 1) and one or more power TSVs 139 (one illustrated in FIG. 1) each extending from the interface die 132 to an uppermost memory stack 136a. The power TSV(s) 139 provide power (e.g., received from one or more of the external power TSVs 118) to the interface die 132 and each of the memory stacks 136. The signal TSVs 138, which include TSVs for carrying control, command (e.g., instructions from the host device 120 regarding one or more operations to be performed by the HBM device 130, such as read data commands, write data commands, and memory management commands), address, and data (DQ) signals, communicably couple a corresponding memory die in each of the memory stacks 136 to a HBM memory controller circuit 133 in the interface die 132 (in addition to various other circuits in the interface die 132). In turn, the HBM memory controller circuit 133 can direct DQ, control, command, and/or address signals to and/or from the host device 120 and/or an external component (e.g., an external storage device coupled to one or more of the external signal TSVs 116 and/or the like).

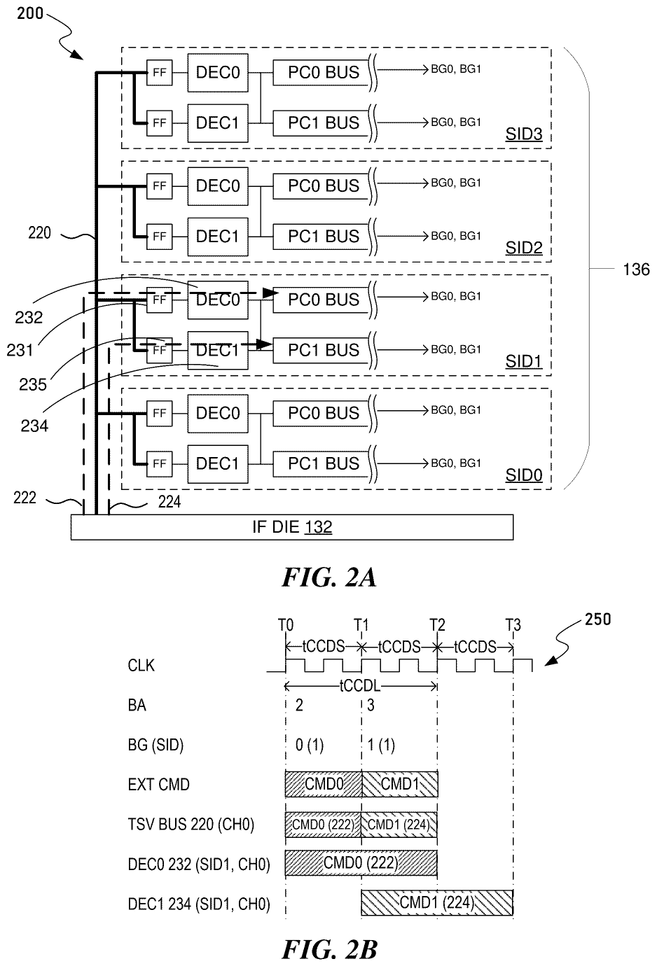

FIG. 2A illustrates a simplified block diagram of a related art HBM device 200, and FIG. 2B illustrates a simplified timing diagram 250 for command signal flow through the command TSVs of a channel of the related art HBM device 200 with respect to a command decode operation using a set of command TSVs (also referred to herein as a “command TSV bus” or a “TSV bus”). The block and timing diagrams can correspond to a related art HBM device with a data rate of 8 Gbps. For clarity and brevity, the DQ data timing is not shown. As used herein a “command TSV bus” or “TSV bus” can refer to one or more TSVs carrying signals (“command signals”) that command and/or instruct one or more components (e.g., DRAM dies) of an HBM device to perform one or more operations. For example, based on the context, a TSV bus can refer to all the command TSVs or a subset of the command TSVs in an HBM device (e.g., command TSVs corresponding to a channel).

FIG. 2A shows a simplified block diagram of a command decoding portion of a related art HBM device 200. For clarity, only a relevant portion of HBM device 200 is illustrated. The interface (IF) die 132 can include a memory controller circuit (e.g., the memory controller circuit 133 of FIG. 1) to receive external commands from a host device (e.g., the host device 120 of FIG. 1) and transmit the external commands on the TSV bus 220 (similar to signal TSVs 138 of FIG. 1). As explained further with respect to FIG. 2B, the HBM device 200 is controlled by one or more clock (CLK) signals that reflect the duration of predetermined timing parameters governing the operation of the HBM device 200, such as the command TSV bus access time (e.g., how much time a TSV bus has to distribute command signals the HBM device 200) and the command decoding time (e.g., of command decoding circuits DEC0 232 and DEC1 234). For example, in related art HBM devices (e.g., HBM device 200), the CLK frequency can be 2 GHz, which equals 0.5 ns per cycle (1/(2*10⁹)), and the command TSV bus timing can be 2 CLK cycles (1 ns) and the command decoding time can be 4 CLK cycles (2 ns). The command signal can include the type of operation to be performed on the memory arrays (e.g., activate, precharge, read, write, or another command operation). In addition, the command signal can have other information such as the SID number of the destination die, pseudo-channel (PC) channel number, and the bank address of the bank group (BG) to receive the command. As reflected in FIG. 2A, a first command (corresponding to command signal 222) and a second command (corresponding to command signal 224) may, for example, both have a destination die associated with SID1. The command signals 222 and 224 can be transmitted sequentially by the host device (e.g., host device 120) and routed one after the other over TSV bus 220 (e.g., channel 0 bus) to SID1. The transmitted command signals 222 and 224 can be received by flip-flop circuits 231 and 235 from the TSV bus 220. The flip-flop circuits 231, 235 for each SID of each channel are alternately enabled so that sequential command signals to that SID and channel (e.g., commands signals 222 and 224 to SID1 on channel 0) are directed to different command decoder circuits (e.g., DEC0 232 or DEC1 234). Depending on the destination SID of the command signal (e.g., SID1), the flip-flop circuit of the appropriate channel and SID will be enabled so that the command signal is directed to the corresponding decoder. For example, in FIG. 2A, when the command signal 222 is transmitted through TSV bus 220, flip-flip circuit 231 can be initially enabled to direct command signal 222 to DEC0 232, and subsequently, when command signal 224 is transmitted through TSV bus 220, flip-flop circuit 235 can be enabled to direct command signal 224 to DEC1 234. Once decoded, the command decoder circuit transmits the command (e.g., activate, precharge, read, write, etc.) to the PC0 bus or the PC1 bus, as appropriate based on the information in the command signal. The command decoders DEC0 232 and DEC1 234 take 4 CLK cycles (2 ns) to decode the command signal. Because each channel of each SID includes two command decoders, while a command decoder DEC0 is decoding a command signal, the other command decoder DEC1 in the same SID can receive another command signal from IF die 132 for decoding. Accordingly, as shown in FIG. 2A, in a related art HBM device (e.g., HBM device 200), the core die area can include two command decoder circuits (e.g., DEC0 232 and DEC1 234) for each channel (e.g., TSV bus 220) of each SID (e.g., SID1), and the command decoder circuits can each have a decoding time of 2 ns.

FIG. 2B is a simplified related art timing diagram for command signal flow through the command TSV bus of a channel (e.g., TSV bus 220) of a related art HBM device (e.g., HBM device 200). For purposes of explanation, it is assumed that BG0 and BG1 are in the same SID (e.g., SID1) and use the same TSV bus (e.g., same set of TSVs corresponding to TSV bus 220 for channel 0 (CH0)) for communicating with the command decoder circuits (e.g., DEC0 232 and DEC1 234). Also, for clarity, the command signal CMD0 222 flow and the command signal CMD1 224 flow are identified with hashed lines going in different directions.

As seen in the timing diagram 250 of FIG. 2B, the timing to transfer the command signal 222 through the TSV bus 220 to the command decoders is 2 CLK cycles (or 1 ns). The timing of command decoders, however, is 4 CLK cycles (2 ns). Accordingly, the flip-flop circuits 231,235 cooperate to alternate the incoming command signals (e.g., CMD0 222 and CMD1 224) between command decoder circuits DEC0 232 and DEC1 234 so that, when one of the decoders is busy decoding, the other decoder is ready to accept the transmitted command signal. For example, at time T0, the IF die 132 transmits a received external command signal 222 (also referred to as “CMD0”) from a host device 120 on the TSV bus 220. The command signal CMD0 is directed to SID1 on channel 0 (CH0). The flip-flop circuits circuit 231, 235 receive the command signal CMD0 and, flip-flop circuit 231 is enabled to send command signal CMD0 to DEC0 232, and DEC0 232 will start to decode command signal CMD0. At time T1, the circuit for TSV bus 220 has completed transmitting the command signal CMD0 to DEC0 232 and the flip-flop circuit 231 is disabled so that an incoming command signal is not transmitted to DEC0 232. In addition, flip-flop circuit 235 is enabled to transmit an incoming command signal to DEC1 234. However, DEC0 232 will still be decoding command signal CMD0 until time T2. Still at T1, the IF die 132 transmits command signal 224 (also referred to herein as “CMD1”) from host device 120 on TSV bus 220, which is then transmitted to DEC1 234 by flip-flip circuit 235. DEC1 234 then starts to decode command signal CMD1. At time T2, the circuit for TSV bus 220 has completed transmitting the command signal CMD1 to DEC1 234 and the flip-flop circuit 235 is disabled so that an incoming command signal is not transmitted to DEC1 234. In addition, flip-flop circuit 231 is enabled to transmit an incoming command signal to DEC0 232. However, DEC1 234 will still be decoding command signal CMD1 until time T3.

With further regard to related art timing diagram 250, those skilled in the art will understand that the host device and the HBM device communicate using an interface protocol, which is provided to and/or configured in the host device prior to the start of memory operations. The timing parameters are part of the interface protocol between a host device and HBM device, and the HBM device may provide to the host device the timing requirements for scheduling memory operations. That is, the HBM device may let the host device know the CLK cycle settings for timing parameters used in typical memory operations such as, for example, timing parameters t_{CCDL} and t_{CCDS}. The timing parameter t_{CCDL} is the read/write (RD/WR) command delay between different banks (BAs) within the same bank group (BG), and the timing parameter t_{CCDS} is the RD/WR command delay between different BGs in the related art system.

Accordingly, as seen in FIG. 2B, there can be two commands (e.g., CMD0 222 and CMD1 224) that access two BGs during the t_{CCDL} CLK cycle period (4 CLK cycles), such as, for example, bank 2 in BG0/SID1 and bank 3 in BG1/SID1. Once the command signal CMD0 222 to bank 2 in BG0/SID1 is issued, the host device (e.g., host device 120) will wait t_{CCDS} CLK cycles (2 CLK cycles) before issuing the command signal CMD1 224 to bank 3 in BG1/SID1. Here, the two bank groups are in the same SID (e.g., SID1). However, depending on how the bank groups are arranged in the HBM device, BGs can be in the same SID or in different SIDs. In addition, due to the interface protocol that the host device follows, prior to the completion of t_{CCDL} CLK cycles, the host device will not issue another command signal to the same bank group. So, t_{CCDL} CLK cycles after scheduling the command signal CMD0 222 to BG0, the host device can schedule (e.g., at time T2) another command signal to a different bank in BG0, if needed.

The host device observes any restrictions in the timing parameters when communicating with the HBM device. For example, as discussed above, based on the t_{CCDL} timing parameter, the host device will not schedule read or write commands to banks in the same bank group within the same t_{CCDL} CLK cycle period. That is, after sending a command (e.g., read, write, etc.) to a bank in a bank group, the host device will wait t_{CCDL} CLK cycles (e.g., 4 CLK cycles for the related art HBM device 200) before scheduling another read or write command to a bank in the same bank group. With respect to the timing parameter t_{CCDS}, after a read or write command to a bank in a bank group, the host device will wait t_{CCDS} CLK cycles (e.g., 2 CLK cycles for the related art HBM device 200) before scheduling another read or write command to a bank in a different bank group. The host device will not violate the timing protocols when scheduling memory commands to the HBM device. That is, the host device will wait at least the number of cycles specified by a timing parameter before issuing successive commands that implicate a timing parameter (e.g., certain timing parameters specify a minimum number of cycles in between commands of certain types). Those skilled in the art understand the interface protocol between the host device and the HBM device and thus, for brevity, will not be further discussed except as needed to explain embodiments of the present disclosure.

As discussed above, with respect to a related art HBM device (e.g., HBM device 200) following timing diagram 250, the timing of the external command signals matches the timing of the TSV bus circuits. For example, the externals commands from the host device (e.g., host device 120) have a timing of 2 CLK cycles (1 ns) and the TSV bus timing is also at 2 CLK cycles (1 ns). Thus, because the TSV bus circuit timing matches that of the external command signals, the circuit for the TSV bus (e.g., TSV bus 220) is able to process a first external command signal (e.g., CMD0) before receiving and processing the next external command signal (e.g., CMD1) on the same TSV bus (e.g., TSV bus 220).

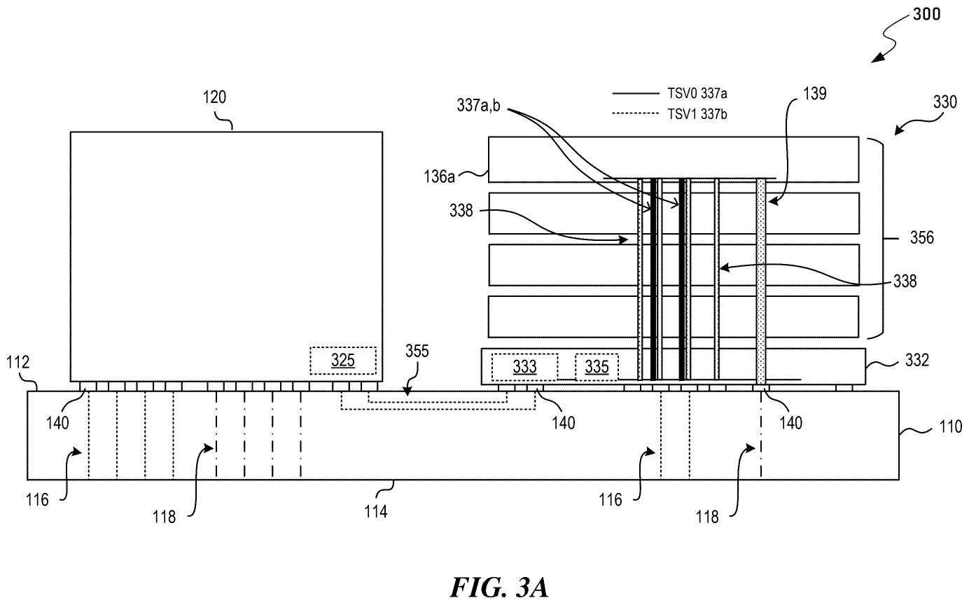

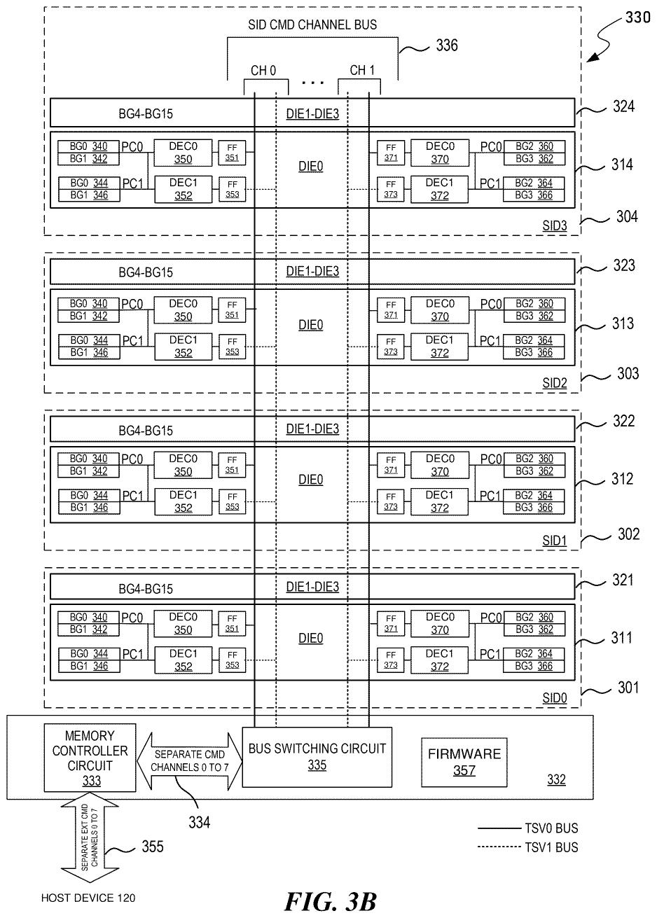

There is, however, a need to increase bandwidth of the communication between the host device and the HBM device on, e.g., communication bus 355 (see FIG. 3A) (e.g., from a data rate of 8 Gbps to greater than 8 Gbps such as, for example, 16 Gbps, 24 Gbps, 32 Gbps or more). In addition, it is desirable to achieve the higher bandwidths without increasing the timings of the TSV bus circuits and the command decoder circuits and without incurring contentions due to a command decoder receiving a new command signal while still processing a previous command signal. Details on the HBM devices, SiP devices having HBM devices, and associated systems and methods consistent with the present disclosure, are set out below. For ease of reference, simplified assemblies of semiconductor packages (and their components) are described herein. It is to be understood, however, that the semiconductor assemblies (and their components) can be moved to, and used in, different spatial orientations without changing the structure and/or function of the disclosed embodiments of the present technology. Additionally, embodiments of the semiconductor packages (and their components) are sometimes described herein with reference to control, command, read, and/or write signals. It is to be understood, however, that the signals can be described using other terminology and/or the embodiments can use other types of signals that are not discussed without changing the structure and/or function of the disclosed embodiments of the present technology.

In exemplary embodiments of the present disclosure, to achieve increased bandwidth, the CLK cycle frequency and, along with the data rate, the command signal rate can be increased accordingly. For example, the CLK frequency used to control the interface between an HBM device and host device may be increased (e.g., external commands received from a host may be associated with a CLK signal having a shorter cycle time). As described above, in related art HBM devices, the command TSV bus that distributes command signals through the HBM device may operate at the same timing as external commands. However, a potential issue with increasing the command TSV bus frequency (i.e., to match the frequency of the clock signal used for external commands) is that, because the command signal paths in the HBM device operate at tight timing margins, an increase in the command signal rate at the TSV bus can result in a slip in the timing margins. That is, an increased command signal rate can mean that the TSV bus timing, the command decoder timing, and/or the memory timing (e.g., memory array timing of the die) will need to run at higher speeds (which requires more power) and/or the timing margins can no longer be met. Accordingly, increasing the TSV bus timing frequency and/or the command decoder circuits to match that of the external bus is not desirable because the power consumption in the HBM device will also increase. Therefore, it is desirable to increase the bandwidth of HBM devices (e.g., the rate at which commands can be received from a host device, such as by increasing the frequency of a clock signal associated with receiving external commands) while maintaining the same timing (e.g., the elapsed real time or “wall-clock time”) of the TSV bus circuits and/or the command decoder circuits found in related art HBM devices (e.g., HBM devices following the JEDEC Standard, High Bandwidth Memory DRAM (HBM4) Specification). In addition, it is also desirable to keep power consumption on the HBM device as low as possible.

A solution, as discussed further below, can be to include multiple command TSV buses in each command channel in the HBM device so that the command signal rate through the HBM device can match the command signal rate from the host device. With matched command signal rates, the wall-clock time of the TSV bus circuit and the command decoder circuit can remain the same as the related art. However, in certain situations, the host device may send a command signal to a command decoder circuit that is busy decoding a previous command signal, which can cause a contention in the HBM device. A solution can be to increase the number of command decoding circuits, but as discussed above, the core die area is limited and increasing the number of command decoder circuits is not desirable.

Embodiments of the present disclosure enable an increased bandwidth in comparison to related art HBM devices while keeping the timings on the command TSV bus circuits and the command decoder circuits the same, and while keeping the number of command decoder circuits per channel per SID the same as in related art HBM devices. In addition, to prevent a command decoder circuit from receiving a new command signal while still processing a previous command signal, embodiments of the present disclosure introduce one or more exclusion timing parameters for the interface protocol between the host device and the HBM device. As described below, these exclusion parameters, observed by a host device, prevent the host device from sending commands in a manner that would cause contention at a command decoder.

To increase the bandwidth, the command and data rates of the external signals from, for example, a host device can be increased (e.g., doubled, tripled, etc.). To accommodate the increased command rate, each HBM channel can include multiple command TSV buses corresponding to the amount of increase and each die can have multiple command decoder circuits associated with the same HBM channel. As described herein, by increasing the number of command TSV buses per-channel in an HBM device in accordance with embodiments of the disclosed technology, each TSV bus can utilize a greater number of CLK cycles to transmit command signals over the TSV bus, such that the wall-clock time utilized by the TSV bus remains unchanged compared to a related art HBM device (e.g., the CLK cycle frequency doubles, but the number of CLK cycles the TSV bus uses to transmit command signals for a given command also doubles). As further described herein, the multiple per-channel TSV buses, in aggregate, are synchronized to the data rate of the external commands, despite the fact that each individual TSV bus may utilize a greater number of CLK cycles to transmit command signals). In addition, each of the command decoders associated with the same HBM channel can be communicatively coupled to a different command TSV bus for the HBM channel. For example, if the command rate is doubled in comparison to a related art HBM device, the number of command TSV buses may be doubled from one to two TSV buses for each HBM channel. In addition, the two command decoder circuits associated with the HBM channel in the die will communicatively couple to a different TSV bus.

A command decoder circuit of an HBM device can decode various commands transmitted from the host device. The commands can include, for example, the activate command, which opens a row for memory operations (e.g., read/write operations) in a bank of an SID, and the precharge command, which deactivates an open row in a bank of an SID. The commands received by the HBM device from the host device (e.g., precharge and activate commands) are known in the art and thus, for brevity, will not be discussed further. In related art systems, as discussed above, the host device avoids contentions in a command decoder circuit (e.g., receiving a new command while still decoding a precious command) by observing the timing parameters of the interface protocol. However, these timing protocols are directed to a related art system with a single TSV bus per channel and, for each SID, two command decoder circuits per channel.

As discussed above (and further below), in exemplary embodiments of the present disclosure, each channel of an HBM device can have multiple TSV buses and, for each SID, a command decoder circuit per TSV bus of a channel. The related art timing protocols may not account for the multiple TSV buses per channel in exemplary embodiments of the present disclosure. Accordingly, the multiple TSV buses may be transparent to the host device when the host device issues commands. Because the related art timing parameters do not account for the number of TSV buses in each channel, the host device may create a contention in a command decoder circuit by transmitting a new command to the command decoder circuit while the command decoder circuit is busy decoding a previous command. To prevent or minimize the contentions in a command decoder circuit, in some embodiments, one or more exclusion timing parameters, each corresponding to one or more commands such as, for example, the precharge command, the activate command, etc., can be introduced as HBM specification changes to the interface protocol between the host device and the HBM device. Each exclusion timing parameter lets a host device know when not to transmit the corresponding command (or commands) to an SID of an HBM channel, and thus avoid sending the command(s) to a command decoder circuit in the SID (associated with the HBM channel) that is already busy.

To ensure that a busy (or potentially busy) command decoder circuit is avoided by the host device, exemplary embodiments of the present disclosure include an exclusion timing parameter that specifies the clock edge on which to exclude a corresponding command (e.g., precharge command, activate command, etc.) to the same SID following a prior command signal. The exclusion timing parameter (and the clock edge on which not to send a command to the same SID of the same channel) can be configured based on the implementation of an HBM device, such as to account for when a TSV bus (from multiple TSV buses) will be used again to transmit a command signal in the HBM device. Thus, because the host device knows the target SID of the previous command signal, and because the clock edge setting of the exclusion timing parameter can be configured to correspond to when the same TSV bus will be used, by communicating the exclusion timing parameter to a host device (e.g., host device 120), the host device knows not to transmit a corresponding command signal (e.g., precharge command, activate command, etc.) to the same SID on the predetermined clock edge following the previous command signal. In some embodiments, a t_{PRESID_EXCL} exclusion timing parameter that is associated with the precharge command can be introduced and defined as the clock edge on which to exclude a precharge command signal to an SID of an HBM channel following a previous command signal to the same SID of the same HBM channel. In some embodiments, a t_{ACTSID_EXCL} exclusion timing parameter that is associated with an activate command can be introduced and defined as the clock edge on which to exclude an activate command to an SID of an HBM channel following a previous command signal to the same SID of the same HBM channel.

In some embodiments, the clock edge setting can be N CLK cycles from the previous command to the same SID and selected so as to correspond to the same TSV bus as that of the previous command signal. The exclusion timing parameter (e.g., t_{PRESID_EXCL}, t_{ACTSID_EXCL}, etc.) can be communicated to the host device. Accordingly, based on the exclusion timing parameter (e.g., t_{PRESID_EXCL}, t_{ACTSID_EXCL}, etc.), the host device knows not to transmit on the N^{th} CLK edge after transmitting a previous command signal, a corresponding command signal (e.g., precharge command, activate command, etc.) to the same SID. In some embodiments, N is equal to a ratio of t_{CCDL}/t_{CCDS}. For example, t_{CCDL} equals 8 CLK cycles and t_{CCDS} equals 2 CLK cycles, then N=4. Depending on the data rate (Gbps) and architecture of the HBM device (e.g., number of data TSV buses per channel, command TSV buses per channel, etc.), one or both timing parameters t_{CCDL} and t_{CCDS} can have other values. However, while the exclusion timing parameter excludes commands to a same SID, because the TSV bus is still available to be accessed, the host device is permitted to transmit consecutive command signals (e.g., precharge commands, activate commands, etc.) on the same TSV bus to a different SID.

Thus, in exemplary embodiments of the present disclosure, the multiple TSV buses for each channel keep the overall data rate through the command TSV buses the same as that of the external command signals to the IF die (e.g., IF die 332) without incurring certain shortcomings (e.g., raising the voltage of the TSV bus to accommodate a faster clock signal). That is, embodiments of the present disclosure increase the number of available TSV command signal paths per channel so that a greater amount of data can be transmitted over the TSVs at any given time. By using multiple TSV command signal paths, consecutive command signals (e.g., activate, precharge, etc.) can use separate TSV command signal paths in a “pipeline” type arrangement with the respective command decoder circuits for the channel. In addition, one or more exclusion timing parameters (e.g., t_{PRESID_EXCL}, t_{ACTSID_EXCL}, etc.) can prevent or mitigate contentions at a command decoder circuit due to a new command signal being transmitted to the command decoder circuit while the command decoder circuit is decoding a previous command signal. In some embodiments, the exclusion timing parameters (e.g., t_{PRESID_EXCL}, t_{ACTSID_EXCL}, etc.) can be programmed in firmware and/or the basic input/output system (BIOS) of the HDM device. The host device (e.g., host device 120) and/or the HBM memory scheduler knows the arrangement of the SIDs. Accordingly, the host device will not schedule a command signal (e.g., precharge command signal, activate command signal, etc.) at a clock edge corresponding to an exclusion timing parameter (e.g., t_{PRESID_EXCL}, t_{ACTSID_EXC}, etc.) that is directed to the same SID as the previous command signal.

FIG. 3A is a partially schematic cross-sectional diagram of an embodiment of a SiP device 300 that is consistent with the present disclosure. SiP device 300 is similar to SiP device 100 and components that are the same are identified with the same reference numbers. Accordingly, the functions of those components will not be discussed further. Host IO circuit 325, HBM memory controller circuit 333, interface die 332, and communication bus 355 have the same functions as host IO circuit 123, HBM memory controller circuit 133, interface die 132, and communication channel 150, respectively, as discussed above with respect to FIG. 1. However, in some embodiments, these components can be configured to and/or may include different circuits to handle an increased data rate (e.g., 16 Gbps, 24 Gbps, 32 Gbps, etc.). In addition, DQ and/or address TSVs 338 can correspond to the signal TSVs 138 discussed above, but may only transmit DQ and address signals. Command signals may be transmitted by command TSV buses 337a, b (a single TSV in each of the TSV buses is illustrated in FIG. 3A). A pair of TSV buses (e.g., TSV bus 337a and TSV bus 337b) can correspond to a channel and transmit signals from/to the respective SIDs and the corresponding channel (e.g., channel 0-7) in the command channel bus in interface die 332. TSV bus 337a can correspond to the TSV0 bus of the channel and TSV bus 337b can correspond to the TSV1 bus of the channel. The interface die 332 can include a bus switching circuit 335 that selectively and communicatively couples the corresponding channel (e.g., channel 0-7) of a command channel bus in the IF die 332 to either of the TSV buses 337a, b (TSV0 and TSV1), as discussed below. In addition, stacks 356 can have a different configuration than stacks 136 in FIG. 1, as discussed below.

FIG. 3B illustrates a block diagram of the HBM device 330 of FIG. 3A. The illustrated embodiment in FIG. 3B has a 4N architecture in that the HBM device 330 includes four stacks SID0-SID3, which can be the same as stacks 356 in FIG. 3A, and each of the stacks SID0-SID3 (labeled 301, 302, 303, and 304, respectively) can include four DRAM dies DIE0-DIE3 (die DIE0 in each stack is labeled 311, 312, 313, and 314, respectively, and dies DIE1-DIE3, in each stack are collectively labeled 321, 322, 323, and 324, respectively). However, other embodiments can have other arrangements in which the number of stacks and/or dies can be fewer or greater. For example, in some embodiments, the number of stacks and/or dies can be 1, 2, or 3.

Each die can have one or more channels that provide independent data access to one or more banks of memory arrays (not shown). Applicant's co-pending U.S. patent application Ser. Nos. 19/201,529, 19/201,569, 19/201,673, and 19/201,689 (respectively corresponding to U.S. Provisional Application Nos. 63/647,437, 63/647,483, 63/647,466, and 63/647,493, filed on May 14, 2024), which are incorporated herein by reference in their entirety, disclose configurations for data buses and circuits that are compatible with the present disclosure, and thus, for brevity, configuration of the data buses and circuits are not discussed further. In the embodiment of FIG. 3B, channels 0 and 1 of SID command channel bus 336 are shown extending through the stacks (or SIDs) 301-304. Dies 311-314 in respective stacks 301-304 have bank groups BG0 340 and BG1 342 corresponding to pseudo-channel PC0 and bank groups BG0 344 and BG1 346 corresponding to pseudo-channel PC1, which can communicatively couple to channel 0. For channel 1, dies 311-314 in respective stacks 301-304 have bank groups BG2 360 and BG3 362 corresponding to pseudo-channel PC0 and bank groups BG0 344 and BG1 346 corresponding to pseudo-channel PC1. Each bank group can include one or more memory banks (e.g., 8 memory banks) that each include one or more memory arrays. The other channels 2-7 (not shown) have similar configurations but communicatively couple to different bank groups in different dies. For example, the other channels may couple to bank groups BG4 through BG15.

In some embodiments, each channel 0-7 of the SID command channel bus 336 can be split into two pseudo-channels that operate semi-independently such as, for example, pseudo-channel PC0 corresponding to DQ bits 0-31 and pseudo-channel PC1 corresponding to DQ bits 32-64. However, in other embodiments, the channels are not split into pseudo-channels. The channels and/or pseudo-channels can provide independent access to corresponding BGs, where each BG can include one or more banks. For example, if a die has 16 banks, each BG can have four banks and an independent channel can provide access to that BG. A die can include fewer banks than 16 such as, for example, 4 banks, 8 banks, etc. In some embodiments, a die can include more than 16 banks. Similarly, the number of BGs in a die can be fewer or greater than four. Segmenting a memory device into banks and bank groups is known in the art and thus, for brevity, will not be further discussed. In addition, those skilled in the art understand that an HBM device can have different arrangements with respect to the number of dies, banks, bank groups, channels, and/or pseudo-channels than in the disclosed embodiments and still be consistent with the present disclosure.

In some embodiments, each channel of each SID can have two command decoder circuits DEC0 and DEC1. For example, as seen in FIG. 3B, channel 0 of SID 301 includes command decoder circuits DEC0 350 and DEC1 352. The output of each command decoder circuit DEC0 350 and DEC1 352 connects to both the PC0 bus and the PC1 bus. That is, the command decoder circuits can select and transmit the decoded command to either of the pseudo-channels (e.g., depending on which one is addressed by the command). In some embodiments, the command decoder circuits can include and/or be connected to flip-flop circuits (e.g., flip-flop circuits 351, 353, 371, and 373 in FIG. 3B), which can be similar to flip-flop circuits 231,232 to ensure that, when enabled, the command signals from the IF die 332 are received by the command decoder circuit corresponding to the SID addressed in the command. Based on the decoded information, the command from, for example, host device 120 can be sent to any one of the bank groups 340, 342, 344, or 346. Similarly, channel 1 of SID 301 includes command decoder circuits DEC0 370 and DEC1 372, and the output of each command decoder circuit DEC0 370 and DEC1 372 connects to the PC0 bus and the PC1 bus. Based on the decoded information, the command from, for example, host device 120 can be sent to any one of the bank groups 360, 362, 364, or 366. The command decoder circuits (DEC0 and DEC1) in the other dies DIE0s of SIDs 302-304 and the command decoder circuits (not shown) in dies DIE1-DIE3 of SIDs 301-304 can be similarly configured.

The following description refers to, as an illustrative example, channel 0 in dies 311, 312, 313, and 314 in respective stacks 301, 302, 303, and 304. However, the description is applicable to channel 1 and the other die groups 321, 322, 323, and 324 (each group representing dies die1-die3), and thus for brevity and clarity is not repeated. As seen in FIG. 3B, each channel 0 to 7 of SID command channel bus 336 can include two command TSV buses (TSV0 and TSV1). For clarity, only the TSV0 and TSV1 buses for channels 0 and 1 are shown, but those skilled in the art understand that the other channels 2-7 can also include a TSV0 bus and a TSV1 bus for each respective bus as well. As discussed further below, the command decoder circuits DEC0 350 and DEC1 352 for each die of channel 0 can be respectively communicatively coupled to the TSV0 bus and the TSV1 bus.

In related art systems each channel includes one command TSV bus per channel to communicate with both command decoders associated with the channel. However, in exemplary embodiments of the present disclosure, the command decoder circuits for each channel of each die communicate with a separate TSV bus of the channel. For example, the DEC0 350 of channel 0 of stack 302 can be communicatively coupled to the TSV0 bus (solid line) and DEC1 352 of channel 0 of stack 302 can be communicatively coupled to the TSV1 bus (dotted line). Likewise, DEC0 370 of channel 1 of stack 302 can be communicatively coupled to the TSV0 bus (solid line) and DEC1 372 of channel 1 of stack 302 can be communicatively coupled to the TSV1 bus (dotted line). The command decoder circuits in the other stacks and for the other channels can be similarly communicatively coupled to the TSV0 bus or the TSV1 bus of the respective channel, as appropriate. Although, two command decoder circuits per channel per SID are discussed above, in other embodiments, if the channel includes three or more TSV buses, there can be three or more command decoder circuits per channel per SID with each command decoder circuit corresponding to a separate TSV bus of the channel.

As seen in FIG. 3B, a bus switching circuit 335 is located in interface die 332 along with the HBM memory controller circuit 333. However, some or all of the functions of bus switching circuit 335 can be incorporated into the HBM memory controller circuit 333 and/or another circuit. The bus switching circuit 335 communicatively couples to the HBM memory controller circuit 333 to receive/transmit the command signals for each channel on interface (IF) command channel bus 334 from/to the HBM memory controller circuit 333. In some embodiments, the external command signals from, for example, host device 120 can be transmitted to memory controller circuit 333 on, for example, separate external command channels 0 to 7, which can be part of communication bus 355. Thus, the HBM memory controller circuit 333 can control external access to the IF command channel bus 334 and bus switching circuit 335 and can manage the command signals to and from the bus switching circuit 335 based on, for example, the memory operation (e.g., activate, precharge, read, write, etc.). Configuration and operation of HBM memory controller circuits are known to those skilled in the art and thus, for brevity, will not be discussed further.

As discussed above, the HBM memory controller circuit 333 can receive the external command signals (e.g., on separate command channels 0-7) from the host device and transmit the command signals to the bus switching circuit 335 on corresponding separate command channels 0-7 of the IF command channel bus 334. The command signals can then be transmitted by the bus switching circuit 335 to the SIDs (e.g., SID0-3) on the corresponding channel 0 to 7 of the SID command channel bus 336. However, each channel 0 to 7 of the IF command channel bus 334 can include a single command signal bus while each channel 0 to 7 of the SID command channel bus 336 can include multiple command signal buses (e.g., TSV buses) such as, for example, a TSV0 bus and a TSV1 bus. Accordingly, in some embodiments, for each channel on the SID command channel bus 336, the bus switching circuit 335 selects one of the TSV buses (e.g., TSV0 bus or TSV1 bus) and communicatively couples the corresponding channel of the IF command channel bus 334 to the selected TSV bus. For example, the bus switching circuit 335 can select and communicatively couple a channel (e.g., channel 0) of the IF command channel bus 334 to a selected TSV bus (e.g., TSV0 bus or TSV1 bus) of the corresponding channel (e.g., channel 0) of the SID command channel bus 336. The selection can be based on, for example, a TSV select signal. The TSV select signal, discussed further below, can be configured such that the bus switching circuit 335 selects between TSV buses in an alternating pattern, in a round-robin pattern, and/or another type of pattern. In some embodiments, the interface protocol can include exclusion timing parameters (e.g., t_{PRESID_EXCL}, t_{ACTSID_EXCL}, etc.). The exclusion timing parameters can be programmed in firmware 357, BIOS, and/or other memory/storage of the HDM device.

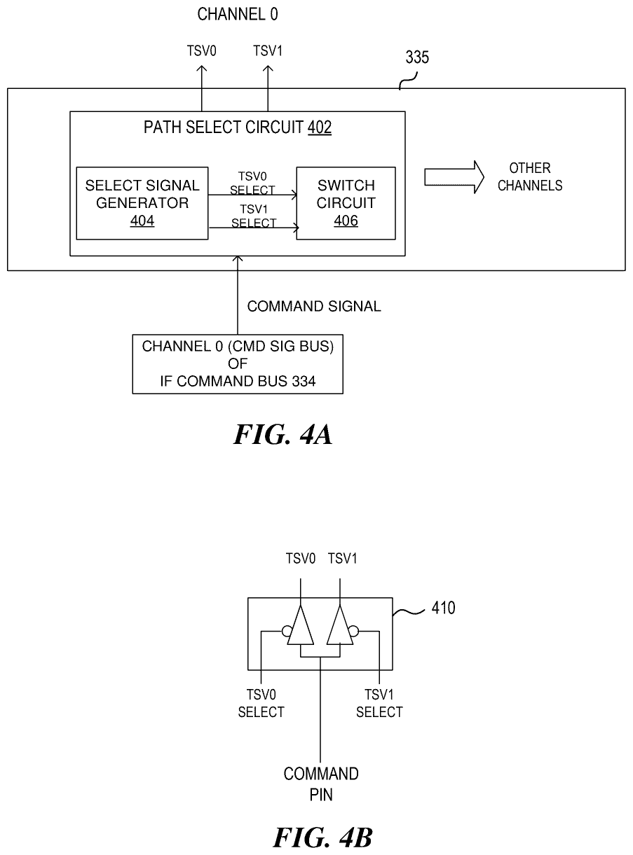

FIG. 4A is a block diagram showing a portion of the bus switching circuit 335 that can select and communicatively couple a TSV bus of a channel to the command signal bus in the IF die 332 corresponding to the channel. For example, in some embodiments, a path select circuit 402 can select between multiple TSV buses (e.g., between two TSV buses, TSV0 and TSV1) for channel 0 and communicatively couple the command signal bus in the IF die 332 for channel 0 to the selected TSV bus. For brevity and clarity, FIG. 4A only shows the path selection circuit for channel 0. However, those skilled in the understand that selection of the appropriate TSV bus for other channels can have similar circuits. That is, each channel may have a corresponding path select circuit 402.

In some embodiments, a command signal from the host device (e.g., host device 120) and/or HBM memory controller circuit 333 (and/or another circuit) is transmitted to the path select circuit 402 of bus switching circuit 335 over channel 0 of the IF command channel bus 334. The path select circuit 402 (and/or another circuit) can include one or more processors, memory, look-up-table, combinatorial logic, state (e.g., flip-flops, latches, etc.), and/or other circuits to determine and select the appropriate TSV bus (e.g., TSV0 or TSV1). For example, in some embodiments, the path select circuit 402 can include select signal generator 404 and a switch circuit 406. The select signal generator 404 can include circuits to generate a path select signal or signals (e.g., TSV0 select and TSV1 select) for selecting between TSVs (or TSV buses) based on a predetermined selection pattern. In some embodiments, the predetermined selection pattern can be an alternating pattern that selects between the multiple TSV buses (e.g., between TSV0 and TSV1) of a channel in a predetermined sequence (e.g., TSV0, TSV1, TSV0 and so on) such that the same TSV bus for the channel is not selected on consecutive command signals for that channel. For example, when the path select circuit 402 receives a command signal from the command signal bus, the path select circuit 402 can select a TSV bus that was not used by the immediately prior command signal for the channel. In other embodiments, the predetermined selection pattern can include selecting a default TSV bus (e.g., TSV0 bus) for every command signal so long as the default TSV and/or the command decoder circuit receiving the command signal on the default TSV bus is not already busy decoding a previous command signal. If the default command decoder is busy, then another TSV bus and the corresponding command decoder for the channel and SID can be selected.

In some embodiments, the switch circuit 406 can include multiple bit-switches corresponding to individual command bit pins of the command signal bus in IF die 332. FIG. 4B shows an embodiment of an individual bit-switch 410 that can be included in the switch circuit 406. As seen in FIG. 4B, the bit-switch 410 can include one or more tri-state inverter circuits (or another appropriate switch circuit) to communicatively couple the command signal bus pin to the appropriate TSV or TSVs. The bit-switch 410 can receive a path select signal or signals from the select signal generator 404 and, based on the path select signal(s), communicatively couple the command pin to the selected TSV (e.g., TSV0 or TSV1). For example, if the TSV0 select signal is enabled, a command bit path between the command pin and a TSV on the TSV0 bus is selected. If the TSV1 select signal is enabled, a command path between the command pin and a TSV on the TSV1 bus is selected. In some embodiments, if no path select signal is enabled, then no command bit path is selected (e.g., because a command signal is not being transmitted to the command decoder circuit). In some embodiments, three or more select signals can be respectively generated if the channel includes three or more TSV buses. In some embodiments, when the channel has two TSV buses, one TSV select signal can be used and bit-switch 410 selects one of the TSVs when the path select signal is enabled and the other TSV when the path select signal is not enabled.

In operation, for the embodiment of FIGS. 3A and 3B, when the HBM memory controller circuit 333 receives a command signal from, for example, host device 120 and transmits the command signal to the bus switching circuit 335 over IF command channel bus 334, the path select circuit 402 for the channel corresponding to the command signal in the bus switching circuit 335 selects either the TSV0 bus or the TSV1 bus based on the predetermined selection pattern discussed above. As a further embodiment, the switch circuit 406 can include multiple 1-to-many demultiplexers, which drive a command signal on to one of the TSVs based on a select signal (e.g., generated by the select signal generator 404).

Accordingly, to increase bandwidth in some embodiments of the present disclosure, the host device (e.g., host device 120) can send command signals at a higher rate (e.g., a command rate corresponding to a data rate of greater than 8 Gbps such as, for example, 16 Gbps, 24 Gbps, 32 Gbps or more). The HBM memory controller circuit 333 and/or the bus switching circuit 335 can then transmit the received command signals to the corresponding command decoder circuits in the SIDs via a command TSV bus. However, in some embodiments, to ensure that the timings of the command TSV bus and that of the command decoder circuits remain the same as those in the related art HBM devices, additional command TSV buses are added for each channel and a path select circuit routes the command signals between multiple TSV buses of a same channel, as discussed above. For example, if there are two TSV buses per channel, the path select circuit 402 can route the commands such that the TSV0 and TSV1 buses (and thus the respective command decoder circuits) can be selected in an alternating pattern. Accordingly, although the increased bandwidth of an HBM device means the timing of the external command signals (e.g., from the host device) is faster (e.g., a new command signal every 0.5 ns for a bandwidth that is doubled), by alternating the TSV buses, the TSV bus circuit timing can be kept the same as the related art HBM device (e.g., TSV bus timings at 1 ns and command decoder circuit timings at 2 ns).

However, in some cases, there is a possibility of a command decoder circuit receiving a new command signal on its TSV bus while the command decoder circuit is still decoding a previous command signal. In related art HBM devices such as that shown in FIGS. 2A and 2B, with a slower CLK frequency and with two command decoder circuits for each channel of each SID, a host device transmitting consecutive command signals (e.g., CMD0 222 and CMD1 224) to the same SID (e.g., SID1) on the same channel is permitted because the consecutive command signals can be routed to different command decoder circuits by the flip-flop circuits. However, with a faster CLK frequency and with one command decoder circuit per TSV bus (e.g., TSV0 bus or TSV1 bus) per SID, the possibility exists that a command decoder circuit will receive a new command signal (e.g., precharge, activate, etc.) from the host device while still decoding a previous command signal.

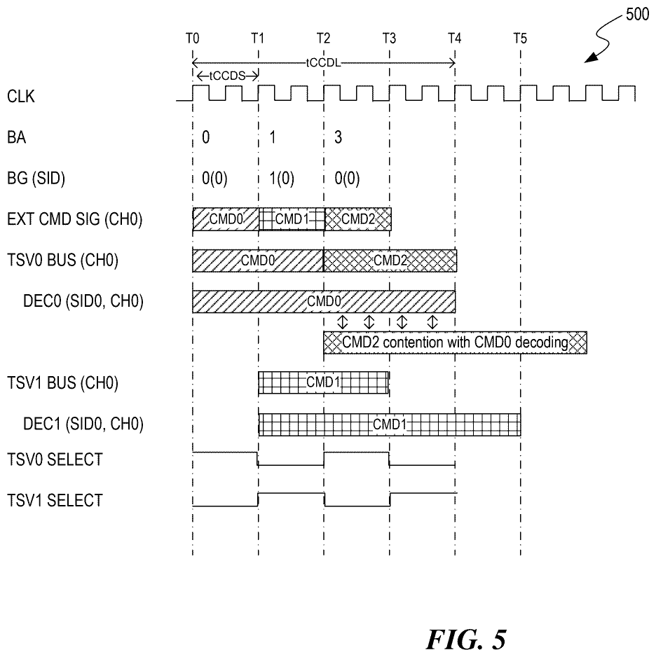

FIG. 5 is a simplified timing diagram 500 for command signal flows to the same command decoder circuit in an HBM device having two TSV buses per channel but the interface protocol between the host device and the HBM device does not include exclusion timing parameters. The timing parameters t_{CCDS} equals 2 CLK cycles (0.5 ns) and t_{CCDL} equals 8 CLK cycles. As seen in FIG. 5, every t_{CCDS} CLK cycle, an external command signal is received by the HBM device (e.g., CMD0 is received at time T0, CMD1 is received at time T1, and CMD2 is received at time T2). The HBM device alternately directs the incoming external command signals to either the TSV0 bus or the TSV1 bus HBM device based on the status of the TSV0 select signal and the TSV1 select signal (e.g., CMD0 to the TSV0 bus at time T0, CMD1 to the TSV1 bus at time T1, and CMD2 to the TSV0 bus at time T2). Because the interface protocol between the host device and the HBM device of FIG. 5 does not include exclusion timing parameters and because the related art timing parameters do not account for multiple TSV buses per channel, all the external command signals from the host device can be directed to a same SID (while keeping within the constraints of other timing parameters set by the interface protocol). For example, as seen in FIG. 5, the command signals CMD0, CMD1, and CMD2 are all directed to SID0. Thus, when CMD0 is directed to the TSV0 bus at time T0, command decoder circuit DEC0 of SID0 starts to decode CMD0. Similarly, when CMD1 is directed to the TSV1 bus at time T1, command decoder circuit DEC1 of SID0 starts to decode CMD1. Because CMD0 and CMD1 are being decoded by separate command decoder circuits in SID0, there is no contention, and some portions of the decoding can proceed concurrently. However, at time T2, when command decoder circuit DEC0 receives command signal CMD2, the command decoder circuit DEC0 is still processing command signal CMD0, and the command signal CMD2 will be in contention with the decoding of the command signal CMD0 in command decoder circuit DEC0. Accordingly, without exclusion timing parameters, there can be issues with the decoding of command signals in the command decoder circuits.

Thus, to avoid issues with respect to decoding conflicts at a command decoder circuit, the host device should not send consecutive command signals (e.g., precharge, activate, etc.) on the same TSV bus to the same SID within the time period (e.g., 2 ns) that the command decoder circuit is decoding a previous command signal. However, as discussed above, the multiple TSV buses for each channel can be transparent to the interface protocol between the host device and the HBM device. That is, the host device may not be aware that an HBM device includes multiple TSV buses per channel. Accordingly, the host device needs to know when not to send a command signal to a command decoder circuit that could be busy decoding another signal. As discussed above, one or more exclusion timing parameters (e.g., t_{PRESID_EXCL}, t_{ACTSID_EXC}, etc.) can be introduced that, when communicated to the host device, let the host device know not to transmit a corresponding command signal (e.g., precharge command, activate command, etc.) on a clock edge that is, for example, N CLK cycles from a previous command to the same SID of an HBM channel as that of the previous command signal. Because the exclusion timing parameter is on a per-channel basis, the host device does not need to know whether the HBM channel has multiple TSV buses. In addition, because the exclusion timing parameter is on a per-channel basis, the exclusion does not affect the other channels, and the host device can send a command signal to the same SID on another HBM channel on the clock edge corresponding to the exclusion timing parameter. As discussed above, the exclusion timing parameters (e.g., t_{PRESID_EXCL} and t_{ACTSID_EXCL}) can be set to 4 (corresponding to 4 CLK cycles from the previous command to that SID), which ensures that the command decoder circuits can operate at approximately a 2 ns rate and are not interrupted by a new command signal while decoding a current command signal. Because the contention at the command decoder circuit is eliminated or mitigated, the HBM device does not require additional command decoder circuits.

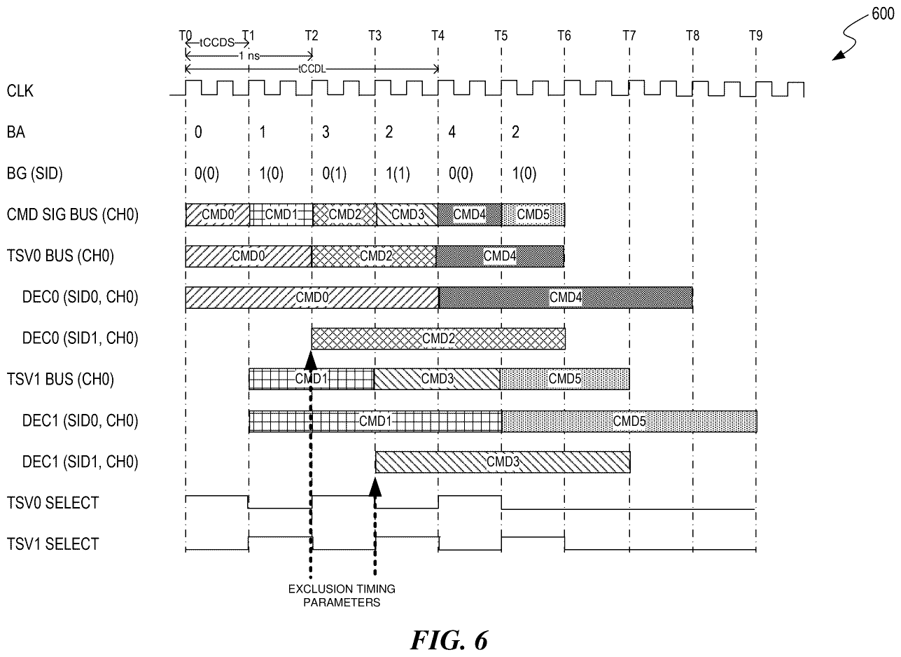

FIG. 6 illustrates a simplified timing diagram 600 for command operations that are consistent with embodiments of the present disclosure. The timing diagram illustrates, in simplified form, the operations of an HBM device that has a data rate of 16 Gbps and two TSV buses per channel. In addition, each channel of an SID in the HBM device has two command decoder circuits, which are connected to different TSV buses. Further, the HBM device interface protocol includes exclusion timing parameters such as, for example, t_{PRESID_EXCL} and t_{ACTSID_EXCL}, which can be a ratio of t_{CCDL}/t_{CCDS}=4, with t_{CCDL} equal to 8 CLK cycles and t_{CCDS} equal to 2 CLK cycles. Accordingly, based on the exclusion timing parameter, the host device knows not to transmit a command signal to the same SID as a previous command signal on the 4^{th} CLK edge after transmitting the previous command signal. As seen in FIG. 6, although the command signals from the external command signal bus are still separated by two CLK cycles as in the system of FIG. 2, due to the increased bandwidth and CLK frequency (e.g., doubling the CLK frequency), the HBM device now receives different command signals from the host that are separated by 0.5 ns (instead of 1 ns). However, although the CLK frequency is increased, the exclusion timing parameters (e.g., t_{PRESID_EXCL} and t_{ACTSID_EXCL}) ensure that the command decoder circuits can operate at approximately a 2 ns rate and are not interrupted by a new command signal while decoding a current command signal.

As seen in FIG. 6, the external command signals are transmitted through the command TSV buses of the HBM device in an alternating pattern. For example, the first, third, and fifth command signals CMD0, CMD2, and CMD3 are transmitted through the TSV0 bus and the second, fourth, and sixth command signals CMD1, CMD3, and CMD5 are transmitted through the TSV1 bus. Accordingly, although the HBM device receives external command signals (e.g., a new command, from the host, over a channel) every 2 CLK cycles (0.5 ns), each command signal can be accessed on the corresponding TSV bus for four CLK cycles (1 ns) thereby maintaining the elapsed real time (compared to related art HBM devices) the TSV bus has to transmit the command signals throughout the HBM device. Furthermore, the command decoder timing of 2 ns (compared to related art HBM devices) need not be changed. In addition, based on the exclusion timing parameter introduced in the interface protocol, for a given channel, the host device knows not send a command signal to a same SID on a clock edge that, in the embodiment of FIG. 6, is equal to 4 CLK cycles after the previous command signal to the same SID.

The command signal flow path is discussed further below with respect to FIG. 6. For clarity, in FIG. 6, the different command signal flows are identified using different hashlines and crosshatches. In addition, command signals CMD0, CMD1, CMD4, and CMD5 are directed to bank groups in SID0, and command signals CMD2, and CMD3 are directed to bank groups in SID1. Also, command signals CMD0, CMD2, and CMD4 are transmitted via the TSV0 bus, and command signals CMD1, CMD3, and CMD5 are transmitted via the TSV1 bus. As further seen in FIG. 6, command signals CMD0 and CMD4 are transmitted to the same command decoder circuit DEC0 in SID0 via the TSV0 bus, and command signals CMD1 and CMD5 are transmitted to the same command decoder circuit DEC1 in SID0 via the TSV1 bus.

In FIG. 6, each time period is t_{CCDS} CLK cycles, which corresponds to 2 CLK cycles (0.5 ns) in this embodiment. The time from T0 to T4 is t_{CCDL} CLK cycles, which corresponds to 8 CLK cycles (2 ns) in this embodiment. As seen in FIG. 6, four command signals can be transmitted by a host device during each t_{CCDL} time period to the HBM device on channel 0, which allows for more bandwidth than related art devices that only receive two command signals over the same elapsed real time. That is, in related art devices (with a slower CLK frequency) 2 ns of elapsed real time corresponds to 4 CLK cycles, which would permit only two command signals (CMD0 and CMD1 as shown in FIG. 2B). As described herein, the present technology enables increasing the CLK frequency, so that more command signals can be transmitted by a host device to an HBM device over a given elapsed real time, without changing the amount of real time during which command signals can be transmitted over TSV buses within the HBM device.

At time T0, the command signal CMD0, which is directed to a BG0 in SID0, is available on the command signal bus (e.g., channel 0 on command channel bus 334) for 2 CLK cycles (0.5 ns) until time T1. In addition, based on, for example, a selection pattern, the TSV0 select signal of path select circuit 402 goes high (and the TSV1 select signal goes low) to select the TSV0 bus corresponding to, for example, channel 0 in SID0. The TSV bus circuit has access to the command signal bus for 2 CLK cycles (0.5 ns) and transmits the command signal CMD0 to command decoder circuit DEC0 in SID0 via the TSV0 bus of channel 0. As seen in FIG. 6, once the transmission starts, the command decoder circuit DEC0 of SID0 has access to the corresponding TSV0 bus for 4 CLK cycles (1 ns) before the TSV0 bus is released. However, the command decoder circuit DEC0 of SID0 can still use 8 CLK cycles (2 ns) to decode the command signal CMD0. Accordingly, the timings of the TSV bus circuits and command decoder circuits can remain the same as that of a related art HBM device that has a data rate of 8 Gbs.

At time T1, the TSV bus circuit for TSV0 and the command decoder circuit for DEC0 of SID0 are still processing the command signal CMD0, but the command signal bus has been released from processing command signal CMD0. The command signal CMD1, which is directed to a BG1 in SID0, is now available on the command signal bus for 2 CLK cycles (0.5 ns) until time T2. In addition, based on, for example, a selection pattern, the TSV1 select signal of path select circuit 402 goes high (and the TSV0 select signal goes low) to select the TSV1 bus corresponding to, for example, channel 0 in SID0. The TSV bus circuit has access to the command signal bus for 2 CLK cycles (0.5 ns) and transmits the command signal CMD1 to command decoder circuit DEC1 in SID0 via the TSV1 bus for channel 0. As seen in FIG. 6, once the transmission starts, the command decoder circuit DEC1 of SID0 has access to the corresponding TSV1 bus for 4 CLK cycles (1 ns) before the TSV1 bus is released. However, the command decoder circuit DEC1 of SID0 can still use 8 CLK cycles (2 ns) to decode the command signal CMD1.

At time T2, the command decoder circuit for DEC0 of SID0 is still processing the command signal CMD0, and the TSV bus circuit for TSV1 and the command decoder circuit for DEC1 of SID0 are still processing the command signal CMD1. However, the command signal bus has been released from processing command signal CMD1, and the TSV0 bus has been released from processing command signal CMD0.

As seen in FIG. 6, time T2 represents the fourth CLK cycle edge (N=4) after the command signal CMD0, which was directed to SID0. Thus, based on an exclusion timing parameter (e.g., t_{PRESID_EXCL} and t_{ACTSID_EXCL}), the host device (e.g., host device 120) knows not to send the next command signal (e.g., precharge, active, etc.) to SID0. As seen in FIG. 6, the host device directs the next command signal CMD2 to BG0 in SID1 and thus avoids a contention with DEC0 in SID0, which is still decoding command signal CMD0.

The command signal CMD2 is available on the command signal bus for 2 CLK cycles (0.5 ns) until time T3. In addition, based on, for example, a selection pattern, the TSV0 select signal of path select circuit 402 goes high (and the TSV1 select signal goes low) to select the TSV0 bus corresponding to, for example, channel 0 in SID1. The TSV bus circuit has access to the command signal bus for 2 CLK cycles (0.5 ns) and transmits the command signal CMD2 to command decoder circuit DEC0 in SID1 via the channel 0 TSV0 bus. As seen in FIG. 6, once the transmission starts, the command decoder circuit DEC0 of SID1 has access to the corresponding TSV0 bus for 4 CLK cycles (1 ns) before the TSV0 bus is released. However, the command decoder circuit DEC0 of SID1 can still use 8 CLK cycles (2 ns) to decode the command signal CMD2.

At time T3, the command decoder circuit for DEC0 of SID0 is still processing the command signal CMD0, and the command decoder circuit for DEC1 of SID0 is still processing the command signal CMD1. In addition, the TSV0 bus is still processing command signal CMD2.However, the command signal bus has been released from processing command signal CMD2, and the TSV1 bus has been released from processing command signal CMD1.

As seen in FIG. 6, time T3 represents the fourth CLK cycle edge (N=4) after the command signal CMD1, which was directed to SID0. Thus, based on an exclusion timing parameter (e.g., t_{PRESID_EXCL} and t_{ACTSID_EXCL}), the host device (e.g., host device 120) knows not to send the next command signal (e.g., precharge, active, etc.) to SID0. As seen in FIG. 6, the host device directs the next command signal CMD3 to BG1 in SID1 and thus avoids a contention with DEC1 in SID0, which is still decoding command signal CMD1.

The command signal CMD3 is available on the command signal bus for 2 CLK cycles (0.5 ns) until time T4. In addition, based on, for example, a selection pattern, the TSV1 select signal of path select circuit 402 goes high (and the TSV0 select signal goes low) to select the TSV1 bus corresponding to, for example, channel 0 in SID1. The TSV bus circuit has access to the command signal bus for 2 CLK cycles (0.5 ns) and transmits the command signal CMD3 to command decoder circuit DEC1 of SID1 via the channel 0 TSV1 bus. As seen in FIG. 6, once the transmission starts, the command decoder circuit DEC1 of SID1 has access to the corresponding TSV1 bus for 4 CLK cycles (1 ns) before the TSV1 bus is released. However, the command decoder circuit DEC1 of SID1 can still use 8 CLK cycles (2 ns) to decode the command signal CMD2.

At time T4, the command decoder circuit for DEC0 of SID0 has completed processing the command signal CMD0 and is free to accept another command signal for decoding. The command decoder circuit for DEC1 of SID0 is still processing the command signal CMD1, the command decoder circuit for DEC0 of SID1 is still processing the command signal CMD2, and the command decoder circuit for DEC1 of SID1 is still processing the command signal CMD3. In addition, the TSV1 bus is still processing command signal CMD3. However, the command signal bus has been released from processing command signal CMD3, and the TSV0 bus has been released from processing command signal CMD2.

The command signal CMD4, which is directed to a BG0 in SID0, is now available on the command signal bus for 2 CLK cycles (0.5 ns) until time T5. Time T4 represents 4 CLK cycles after time T2. However, because command signal CMD2 at time T2 is directed to SID1 and command signal CMD4 at time T4 is directed to SID0, the exclusion timing parameters (e.g., t_{PRESID_EXCL} and t_{ACTSID_EXCL}) do not apply in this case. Based on, for example, a selection pattern, the TSV0 select signal of path select circuit 402 goes high (and the TSV1 select signal goes low) to select the TSV0 bus corresponding to, for example, channel 0 in SID0. The TSV bus circuit has access to the command signal bus for 2 CLK cycles (0.5 ns) and transmits the command signal CMD4 to command decoder circuit DEC0 in SID0 via the TSV0 bus for channel 0. As seen in FIG. 6, once the transmission starts, the command decoder circuit DEC0 of SID0 has access to the corresponding TSV0 bus for 4 CLK cycles (1 ns) before the TSV0 bus is released. However, the command decoder circuit DEC0 of SID0 can still use 8 CLK cycles (2 ns) to decode the command signal CMD4.

At time T5, the command decoder circuit for DEC1 of SID0 has completed processing the command signal CMD1 and is free to accept another command signal for decoding. The command decoder circuit for DEC0 of SID0 is still processing the command signal CMD4, the command decoder circuit for DEC0 of SID1 is still processing the command signal CMD2, and the command decoder circuit for DEC1 of SID1 is still processing the command signal CMD3. In addition, the TSV0 bus is still processing command signal CMD4. However, the command signal bus has been released from processing command signal CMD4, and the TSV1 bus has been released from processing command signal CMD3.

The command signal CMD5, which is directed to a BG1 in SID0, is now available on the command signal bus for 2 CLK cycles (0.5 ns) until time T6. Time T5 represents 4 CLK cycles after time T3. However, because command signal CMD3 at time T3 is directed to SID1 and command signal CMD5 at time T5 is directed to SID0, the exclusion timing parameters (e.g., t_{PRESID_EXCL} and t_{ACTSID_EXCL}) do not apply in this case. Based on, for example, a selection pattern, the TSV1 select signal of path select circuit 402 goes high (and the TSV0 select signal goes low) to select the TSV1 bus corresponding to, for example, channel 0 in SID0. The TSV bus circuit has access to the command signal bus for 2 CLK cycles (0.5 ns) and transmits the command signal CMD5 to command decoder circuit DEC1 in SID0 via the TSV1 bus for channel 0. As seen in FIG. 6, once the transmission starts, the command decoder circuit DEC1 of SID0 has access to the corresponding TSV1 bus for 4 CLK cycles (1 ns) before the TSV1 bus is released. However, the command decoder circuit DEC1 of SID0 can still use 8 CLK cycles (2 ns) to decode the command signal CMD5.

At time T6, the command decoder circuit for DEC0 of SID1 has completed processing the command signal CMD2 and the command signal bus has been released from processing command signal CMD5. However, the command decoder circuit for DEC1 of SID1 is still processing the command signal CMD3, the command decoder circuit for DEC0 of SID0 is still processing the command signal CMD4, and the command decoder circuit for DEC1 of SID0 is still processing the command signal CMD5. In addition, the TSV1 bus still processing CMD5. Further, because there are no command signals to process on channel 0, both the TSV0 and TSV1 select signals of path select circuit 402 are low.

At time T7, the command decoder circuit for DEC1 of SID1 has completed processing the command signal CMD3, at time T8, the command decoder circuit for DEC0 of SID0 has completed processing the command signal CMD4, and at time T9, the command decoder circuit for DEC1 of SID0 has completed processing the command signal CMD5.

As seen in FIG. 6, because there is more than one TSV bus per channel, the command signals can be processed by the TSV bus circuits and the command decoder circuits in staggered overlapping patterns. Accordingly, in exemplary embodiments of the present disclosure, the bandwidth can be increased while keeping the command signal bus saturated during operation of the HBM device. In addition, by introducing exclusion timing parameters (e.g., t_{PRESID_EXCL} and t_{ACTSID_EXCL}), contentions in a command decoder circuit with respect to receiving a new command signal while the current command signal is still being processed can be eliminated or mitigated.

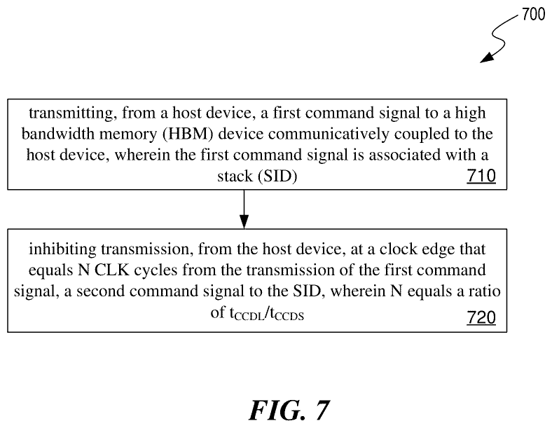

FIG. 7 illustrates a flow chart 700 showing the method steps performed by one or more processors and/or hardwired circuitry in the SiP device such as, for example, the host device. In step 710, a host device transmits a first command signal to a high-bandwidth memory (HBM) device communicatively coupled to the host device, wherein the first command signal is associated with a stack (SID). For example, as discussed above and as seen in FIG. 6, the host device can transmit a first command signal (e.g., CMD0) to the HBM device.

In step 720, the host device is inhibited from transmitting, at a clock edge that equals N CLK cycles from the transmission of the first command signal, a second command signal to the SID. The N CLK cycles can equal a ratio of t_{CCDL}/t_{CCDS}. For example, as seen in FIG. 6, t_{CCDL} equals 8 CLK cycles and t_{CCDS} equals 2 CLK cycles, and thus, N is a ratio of t_{CCDL}/t_{CCDS}, which equals 4. The host device, at a clock edge that equals N CLK cycles (e.g., 4 CLK cycles) from the transmission of the first command signal (e.g., CMD0) is inhibited from transmitting the second command signal (e.g., CMD2) to the same SID (e.g., SID0). For example, at time T2, which is 4 CLK cycles from the transmission of CMD0 at time T0, CMD2 is inhibited by the exclusion timing parameters from being transmitted to SID0 and, instead, CMD2 is transmitted to SID1.

From the foregoing, it will be appreciated that embodiment of the present disclosure provide increased bandwidth over related art HBM devices while ensuring that the DRAM memory array timings, the TSV bus timings, and the DQ bus timings are all synchronized. For example, it will be appreciated that, in some embodiment, the data rate at the DQ pins are increased while still keeping the same memory array as related art HBM devices. In addition, by relaxing the frequency cycle timings in the TSV bus, embodiments of the present disclosure can perform low voltage switching in the TSV to keep the power consumption low. Further, embodiments of the present disclosure increase the number of bank groups that can be opened during a t_{CCDL} CLK cycle period in comparison to a related art HBM device, while still maintaining a 4N architecture and the same number of banks.

In addition, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally”, “approximately,” and “about” are used herein to mean within at least within 10 percent of a given value or limit. Purely by way of example, an approximate ratio means within ten percent of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Thus, computer-readable media can comprise computer-readable storage media (e.g., “non-transitory” media) and computer-readable transmission media.

It will also be appreciated that various modifications may be made without deviating from the disclosure or the technology. For example, the dies in the HBM device can be arranged in any other suitable order (e.g., with the non-volatile memory die(s) positioned between the interface die and the volatile memory dies; with the volatile memory dies on the bottom of the die stack; and the like). Further, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. For example, although discussed herein as using a non-volatile memory die (e.g., a NAND die and/or NOR die) to expand the memory of the HBM device, it will be understood that alternative memory extension dies can be used (e.g., larger-capacity DRAM dies and/or any other suitable memory component). While such embodiments may forgo certain benefits (e.g., non-volatile storage), such embodiments may nevertheless provide additional benefits (e.g., reducing the traffic through the bottleneck, allowing many complex computation operations to be executed relatively quickly, etc.).

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A system-in-package (SiP) device, comprising:
a base substrate;
a processing unit carried by the base substrate; and
a high-bandwidth memory (HBM) device carried by the base substrate and electrically coupled to the processing unit,
wherein the HBM device comprises one or more stacks (SIDs), each stack (SID) having one or more memory dies, each memory die associated with one or more channels,
wherein the processing unit is configured such that, after transmitting a first command signal to a first SID of the one or more SIDs on a channel of the one or more channels, at a predetermined clock edge from the transmission of the first command signal that is based on an exclusion timing parameter, the processing unit does not transmit a second command signal to the first SID on the channel,
wherein the exclusion timing parameter is based on t_{CCDL} and t_{CCDS}, and
wherein t_{CCDL} corresponds to a delay between commands associated with different banks in a same bank group, and t_{CCDS} corresponds to a delay between commands associated with different banks in different bank groups on a same stack.

2. The SiP device of claim 1, wherein the predetermined clock edge corresponds to a ratio of t_{CCDL}/t_{CCDS}, and
wherein t_{CCDS} equals 2 CLK cycles and t_{CCDL} equals 8 CLK cycles.

3. The SiP device of claim 1, wherein the HBM device further comprises a plurality of through-silicon via (TSV) buses associated with a same channel,
wherein each die of the one or more dies includes a plurality of command decoder circuits associated with the same channel, and
wherein each command decoder circuit of the plurality of command decoder circuits is associated with a different TSV bus in the plurality of TSV buses.

4. The SiP device of claim 1, wherein the second command signal is one of a precharge command signal or an activate command signal, and
wherein the exclusion timing parameter is on a per channel basis.

5. The SiP device of claim 1, wherein the processing unit is configured such that the second command signal to a second SID that is different from the first SID is permitted at the predetermined clock edge.

6. The SiP device of claim 1, wherein the HBM device further comprises a bus switching circuit configured to select a TSV bus from a plurality of TSV buses corresponding to a same channel of the one or more channels and to communicatively couple a command signal bus carrying the first command signal from the processing unit to the TSV bus, and
wherein the bus switching circuit is adapted such that a same TSV bus for the channel is not selected on consecutive command signals.

7. The SiP device of claim 6, wherein the plurality of TSV buses includes a first TSV bus and a second TSV bus.

8. A high-bandwidth memory (HBM) device, comprising:
a plurality of through-silicon via (TSV) buses associated with a same channel;
one or more stacks (SIDs), each stack (SID) having one or more dies, wherein each die includes a plurality of command decoder circuits associated with the same channel; and
a bus switching circuit configured to select a TSV bus from the plurality of TSV buses and to communicatively couple a command signal bus for carrying a command signal from a host device to the selected TSV bus,
wherein the HBM device is configured with an exclusion timing parameter that after a first command signal from the host device to a first SID of the one or more SIDs, inhibits a second command signal from the host device to the first SID at a clock edge that is N CLK cycles from a transmission of the first command signal,
wherein N corresponds to a ratio of t_{CCDL}/t_{CCDS}, and
wherein t_{CCDL} corresponds to a delay between commands associated with different banks in a same bank group, and t_{CCDS} corresponds to a delay between commands associated with different banks in different bank groups on a same stack.

9. The HBM device of claim 8, wherein t_{CCDS} equals 2 CLK cycles, t_{CCDL} equals 8 CLK cycles, and N equals 4.

10. The HBM device of claim 8, wherein each command decoder circuit of the plurality of command decoder circuits is associated with a different TSV bus in the plurality of TSV buses.

11. The HBM device of claim 8, wherein the second command signal is one of a precharge command signal or an activate command signal, and
wherein the exclusion timing parameter is on a per channel basis.

12. The HBM device of claim 8, wherein the second command signal to a second SID that is different from the first SID is permitted at the clock edge that is N CLK cycles from the transmission of the first command signal.

13. The HBM device of claim 8, wherein the bus switching circuit is adapted such that a same TSV bus for the channel is not selected on consecutive command signals.

14. The HBM device of claim 8, wherein the plurality of TSV buses includes a first TSV bus and a second TSV bus.

15. A method, comprising:
transmitting, from a host device, a first command signal to a high-bandwidth memory (HBM) device communicatively coupled to the host device, wherein the first command signal is associated with a stack (SID); and
inhibiting transmission, from the host device, at a clock edge that equals N CLK cycles from the transmission of the first command signal, a second command signal to the SID,
wherein N equals a ratio of t_{CCDL}/t_{CCDS,} and
wherein t_{CCDL} corresponds to a delay between commands associated with different banks in a same bank group, and t_{CCDS} corresponds to a delay between commands associated with different banks in different bank groups on a same stack.

16. The method of claim 15, wherein t_{CCDS} equals 2 CLK cycles, t_{CCDL} equals 8 CLK cycles, and N equals 4.

17. The method of claim 15, further comprising:
transmitting, from the host device, at the clock edge that equals N CLK cycles from the transmission of the first command signal, the second command signal to a second SID that is different from the SID.

18. The method of claim 15, wherein the second command signal is one of a precharge command signal or an activate command signal.

19. The method of claim 15, wherein a communication data rate between the host device and the HBM device is 16 Gbps.

20. The method of claim 15, wherein the first command signal is transmitted on a first HBM channel, and wherein the method further comprises:
transmitting, from the host device, at the clock edge that equals N CLK cycles from the transmission of the first command signal, the second command signal to the first SID on a second HBM channel that is different from the first HBM channel.
